(19) United States
(12) Patent Application Publication
(10) Pub. No.: US 2025/0031316 A1
(43) Pub. Date: Jan. 23, 2025

(54) METHODS FOR FORMING CIRCUIT PATTERN ON SUBSTRATE USING METAL FOIL WITH LOW SURFACE ROUGHNESS

(71) Applicant: YMT CO., LTD., Incheon (KR)

(72) Inventors: Sung Wook CHUN, Incheon (KR); Bo Mook CHUNG, Incheon (KR); Myong Hwan PARK, Incheon (KR); Jae Hak AN, Anyang si (KR); Dongmin YANG, Incheon (KR); Dea Geun KIM, Incheon (KR); Hyun Seung KANG, Gwangmyeong-si (KR)

(21) Appl. No.: 18/707,497

(22) PCT Filed: Nov. 23, 2023
(86) PCT No.: PCT/KR2022/018540

§ 371 Date: May 3, 2024

(30) Foreign Application Priority Data
Nov. 29, 2021 (KR) 10-2021-0167647

(51) Int. Cl. H05K 3/04; C23C 18/16; C23C 18/38; C25D 5/02; C25D 5/56; H05K 3/42

(52) U.S. Cl. CPC H05K 3/04; C23C 18/1646; C23C 18/38; C25D 5/022; C25D 5/56; H05K 3/42

(57) ABSTRACT

Provided are methods for forming a circuit pattern on a substrate by a process for circuit pattern formation, such as a semi-additive process (SAP) or a modified semi-additive process (mSAP), using a thin metal foil with low surface roughness.

### TECHNICAL FIELD

The present invention relates to methods for forming a circuit pattern on a substrate by a process for circuit pattern formation, such as a semi-additive process (SAP) or a modified semi-additive process (mSAP), using a thin metal foil with low surface roughness.

### BACKGROUND ART

Various processes for forming circuit patterns on substrates in the manufacture of printed circuit boards are known, for example, subtractive, additive, full additive, and semi-additive, modified semi-additive processes.

According to the semi-additive process (SAP), via holes are processed in a substrate where a metal base is bonded to an insulating base, electroless copper plating is performed, a dry film is bonded, exposed, and developed, and copper electroplating is then performed to form a circuit pattern. However, the electroless copper plating makes it difficult to ensure sufficient adhesion to the insulating base. Before the electroless copper plating, the surface of the insulating base is generally roughened to ensure sufficient adhesion to the insulating base by a desmear process. However, there is a limitation in roughening the surface of the insulating base whose type and characteristics become more diverse. That is, when the electroless copper plating of the insulating base in which the via holes are formed is performed for the subsequent copper electroplating, a copper seed layer formed by the electroless copper plating does not exhibit sufficient adhesion (bonding) to the insulating base, which negatively affects the formation of the desired circuit pattern.

Accordingly, the existing processes have difficulty in ensuring sufficient adhesion to insulating bases. Further, the non-uniform roughness of insulating bases makes it difficult to form microcircuits. Thus, there is a need to develop a technique that ensures sufficient adhesion to insulating bases to facilitate control over fine circuit pattern formation processes.

### DETAILED DESCRIPTION OF THE INVENTION

### Problems to be Solved by the Invention

The present invention intends to provide a method for forming a circuit pattern on a substrate by a process for circuit pattern formation, such as an SAP or mSAP, using a thin metal foil with low surface roughness.

### Means for Solving the Problems

One aspect of the present invention provides a method for forming a circuit pattern on a substrate, including preparing a substrate in which a metal base is bonded to an insulating base, bonding a metal foil having one or more flat-topped projections onto the insulating base, and transferring the surface roughness of the metal foil to the insulating base.

In one embodiment, the metal foil may be bonded onto the insulating base such that the flat-topped projections face the surface of the insulating base.

In one embodiment, each of the flat-topped projections may include a protrusion having a truncated conical or truncated polygonal pyramidal shape and a plateau provided at the top end of the protrusion.

In one embodiment, the protrusion may have a plurality of microprojections formed on the surface thereof.

In one embodiment, the surface roughness (Rz) of the metal foil may be 0.05 to 1.5 μm.

In one embodiment, the thickness of the metal foil may be 5 μm or less.

In one embodiment, the metal foil may be formed by electroless plating.

In one embodiment, 1 to 100 pores per unit area (μm²) may be formed on the surface of the insulating base to which the roughness is transferred.

The present invention also provides a method for forming a circuit pattern on a substrate, including preparing a substrate in which a metal base is bonded to an insulating base, bonding a metal foil having one or more flat-topped projections onto the insulating base, forming one or more via holes penetrating the insulating base and the metal foil, forming a seed part on the inner walls of the via holes, arranging a dry film on the metal foil and patterning the dry film, and electroplating the via holes exposed by the patterning to form a circuit pattern.

The present invention also provides a method for forming a circuit pattern on a substrate, including preparing a substrate in which a metal base is bonded to an insulating base, bonding a metal foil having one or more flat-topped projections onto the insulating base, peeling the metal foil having a surface roughness formed by the projections to transfer the surface roughness of the metal foil to the insulating base, forming one or more via holes penetrating the insulating base, forming a seed part on the surface of the insulating base having the via holes and on the inner walls of the via holes, arranging a dry film on the insulating base on which the seed part is formed and patterning the dry film, and electroplating the via holes exposed by the patterning to form a circuit pattern.

### Effects of the Invention

According to each of the methods of the present invention, a circuit pattern is formed on a substrate by bonding a thin metal foil with low surface roughness onto an insulating base, forming via holes, and performing electroless plating and/or electroplating. Therefore, the circuit pattern can be formed at low cost while ensuring sufficient adhesive strength (bonding strength) to the insulating base and facilitating process control.

### BRIEF DESCRIPTION OF THE DRAWINGS

FIG. 1 is a flow diagram illustrating a method for forming a circuit pattern on a substrate according to one embodiment of the present invention;

FIGS. 2 and 3 are reference views for explaining metal foils used in methods of the present invention;

FIG. 4 is a flow diagram illustrating a method for forming a circuit pattern on a substrate according to a further embodiment of the present invention;

FIGS. 5 and 6 are images for explaining Experimental Example 1;

FIG. 7 is an image for explaining Experimental Example 2; and

FIG. 8 illustrates a method for forming a circuit using a primer according to one embodiment of the present invention.

### MODE FOR CARRYING OUT THE INVENTION

It should be understood that the terms and words used in the specification and the claims are not to be construed as having common and dictionary meanings but are construed as having meanings and concepts corresponding to the technical spirit of the present invention in view of the principle that the inventor can define properly the concept of the terms and words in order to describe his/her invention with the best method.

It will be understood that when an element is referred to as being “on” another element, it can be directly on the other element or intervening elements may also be present. In the case where an element and another element change in position relative to each other, “on” can be interpreted as “under”.

The individual steps described herein may be performed sequentially, in the reverse order or by appropriately changing the order during processing.

The present invention is directed to a method for forming a circuit pattern on a substrate, including preparing a substrate in which a metal base is bonded to an insulating base, bonding a metal foil having one or more flat-topped projections onto the insulating base, and transferring the surface roughness of the metal foil to the insulating base.

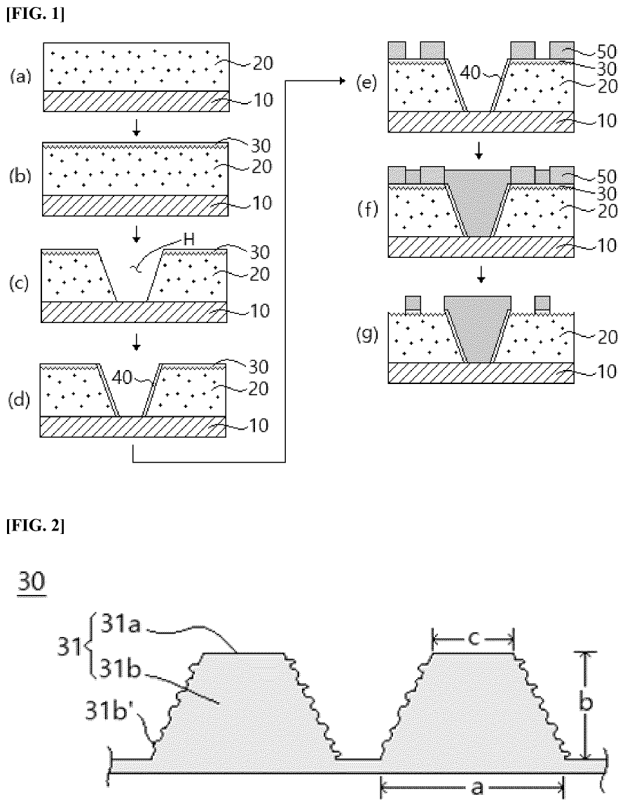

Referring specifically to FIG. 1, an insulating base is bonded to the upper surface of a metal base to prepare a base portion of a substrate.

The metal base 10 serves to ensure heat dissipation performance of the substrate and electrically connect between multilayer circuit patterns. The metal base 10 may include one or more metal components commonly known in the art. Specifically, the metal base 10 may include one or more metals selected from the group consisting of copper (Cu) and titanium (Ti).

The insulating base 20 serves to ensure the insulating performance of the substrate. The insulating base 20 may be made of a material commonly known in the art, specifically a prepreg in which an insulating resin such as an epoxy or polyimide resin is impregnated into a fiber base such as a carbon or glass fiber.

The metal foil 30 having one or more flat-topped projections is bonded onto the insulating base 20.

Any conventional method for metal foil lamination may be used without particular limitation to bond the metal foil 30 onto the insulating base 20. Specifically, the metal foil is primarily laminated by pressurization at a temperature of 100° C. and a pressure of 5 kg/m² for 60 seconds and is then secondarily laminated by pressurization at a temperature of 100° C. and a pressure of 5 kg/m² for 60 seconds. After pressurization, curing may be performed at 130° C. for 30 minutes and at 165° C. for 30 minutes.

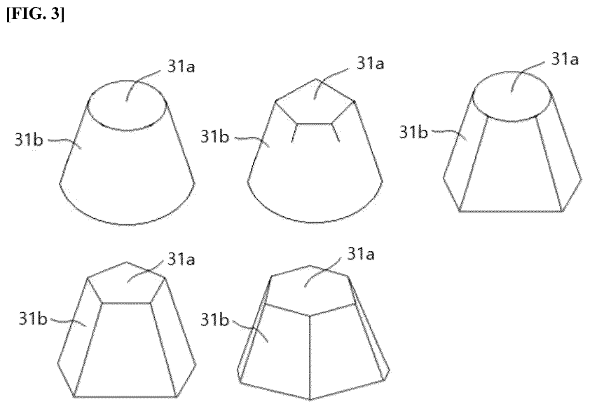

The formation of one or more, that is, a plurality of projections with flat tops allows the metal foil 30 to have a specific surface feature (structure). Referring specifically to FIG. 2, the metal foil 30 may have a structure in which a plurality of surface projections 31 are present (formed) on the surface. The projections 31 may be metal crystal particles protruding vertically upward from the surface of the metal foil 30. Specifically, each of the projections 31 may include a protrusion 31b and a plateau 31a.

The protrusions 31b of the projections 31 are portions protruding from the surface of the metal foil 30 and may have a truncated conical or truncated polygonal pyramidal shape. Specifically, the protrusions 31b have a truncated conical shape with a flat surface (lateral surface) or a truncated polygonal pyramidal shape with angulated surfaces, as illustrated in FIG. 3. This shape enhances anchoring of the metal foil to the insulating base 20 so that the metal foil 30 can be bonded to the insulating base 20 with a high adhesive strength. More specifically, the protrusions 31b may have at least one truncated polygonal pyramidal shape selected from the group consisting of truncated pentagonal pyramidal, truncated hexagonal pyramidal, truncated heptagonal pyramidal, and truncated octagonal pyramidal shapes.

Each of the protrusions 31b may have a plurality of microprojections 31b′ to enhance the adhesion to the insulating base 20 due to its increased surface area. The formation of the microprojections 31b′ allows the protrusions 31b to have a surface roughness (Ra) of 0.05 to 0.3 μm, specifically 0.08 to 0.2 μm. Here, the surface roughness (Ra) of the protrusions 31b can be defined as that of the lateral surfaces of the protrusions 31b other than the plateaus 31a.

Meanwhile, the ratio of the height (b) of each protrusion 31b to the length (a) of the base of the protrusion 31b may be in the range of 0.4 to 1.5 (b/a), specifically 0.6 to 1.2 (b/a). When the ratio (b/a) is within the range defined above, the adhesion between the metal foil 30 and the insulating base 20 can be enhanced.

The plateaus 31a of the projections 31 are flat surfaces of the upper ends of the protrusions 31. The plateaus 31a may be upper surfaces of the protrusions 31b having a truncated conical or truncated polygonal pyramidal shape. Specifically, the plateaus 31a may have a circular, elliptical or polygonal shape. Fine irregularities may be densely formed to provide flat surfaces, which can also be considered to be encompassed within the scope of the plateaus 31a.

In each of the projections 31, the ratio of the length (c) of the plateau 31a to the length (a) of the base of the protrusion 31b may be in the range of 0.1 to 0.7 (c/a), specifically 0.2 to 0.6 (c/a). When the ratio (c/a) is within the range defined above, the adhesion between the metal foil 30 and the insulating base 20 can be enhanced. The length (c) of the plateau 31a refers to the largest length in the plane of the plateau 31a.

The number of the projections 31 per unit area (1 μm²) of the metal foil 30 may be 25 or less, specifically 5 to 20, more specifically 7 to 15, taking into consideration the adhesion between the metal foil 30 and the insulating base 20, the resolution of the circuit pattern, etc.

The metal foil 30 including one or more projections 31 may be formed by electroless plating. Specifically, the metal foil 30 is formed by forming a metal seed foil by electroless plating, after which crystal grains continuously grow on the metal seed foil to form a plurality of projections 31 on the surface. Electroless plating makes the metal foil 30 smaller in thickness, lower in surface roughness, and more porous than electroplating. The metal foil 30 formed by electroless plating can be efficiently introduced into a process for forming a circuit pattern on a substrate.

The composition of an electroless plating solution used to form the metal foil 30 is not particularly limited and may include a metal ion source and a nitrogenous compound.

The metal ion source may be specifically a copper ion source selected from the group consisting of copper sulfate, copper chloride, copper nitrate, copper hydroxide, copper sulfamate, and mixtures thereof. The metal ion source may be present at a concentration of 0.5 to 300 g/L, specifically 100 to 200 g/L.

The nitrogenous compound diffuses metal ions to form the plurality of projections 31 on the surface of a metal seed foil formed by the metal ion source. Specifically, the nitrogenous compound may be selected from the group consisting of purine, adenine, guanine, hypoxanthine, xanthine, pyridazine, methylpiperidine, 1,2-di-(2-pyridyl)ethylene, 1,2-di-(pyridyl)ethylene, 2,2′-dipyridylamine, 2,2′-bipyridyl, 2,2′-bipyrimidine, 6,6′-dimethyl-2,2′-dipyridyl, di-2-furyl ketone, N,N,N′,N′-tetraethylenediamine, 1,8-naphthyridine, 1,6-naphthyridine, terpyridine, and mixtures thereof. The nitrogenous compound may be present at a concentration of 0.01 to 10 g/L, specifically 0.05 to 1 g/L.

The electroless plating solution may further include one or more additives selected from the group consisting of a chelating agent, a pH adjusting agent, and a reducing agent.

Specifically, the chelating agent may be selected from the group consisting of tartaric acid, citric acid, acetic acid, malic acid, malonic acid, ascorbic acid, oxalic acid, lactic acid, succinic acid, potassium sodium tartrate, dipotassium tartrate, hydantoin, 1-methylhydantoin, 1,3-dimethylhydantoin, 5,5-dimethylhydantoin, nitriloacetic acid, triethanolamine, ethylenediaminetetraacetic acid, tetrasodium ethylenediaminetetraacetate, N-hydroxyethylenediamine triacetate, pentahydroxypropyldiethylenetriamine, and mixtures thereof. The chelating agent may be present at a concentration of 0.5 to 600 g/L, specifically 300 to 450 g/L.

Specifically, the pH adjusting agent may be selected from the group consisting of sodium hydroxide, potassium hydroxide, lithium hydroxide, and mixtures thereof. The pH adjusting agent can adjust the pH of the electroless plating solution to 8 or higher, specifically 10 to 14, more specifically 11 to 13.5.

Specifically, the reducing agent may be selected from the group consisting of formaldehyde, sodium hypophosphite, sodium hydroxymethanesulfinate, glyoxylic acid, borohydride, dimethylamine borane, and mixtures thereof. The reducing agent may be present at a concentration of 1 to 20 g/L, specifically 5 to 20 g/L.

The conditions for the electroless plating to form the metal foil 30 may be appropriately adjusted depending on the thickness of the metal foil 30. Specifically, the electroless plating temperature may be 20 to 60° C., specifically 30 to 40° C. and the electroless plating time may be 2 to 30 minutes, specifically 5 to 20 minutes.

The thickness of the metal foil 30 formed by electroless plating may be 5 μm or less, specifically 0.1 to 1.2 μm. When the thickness of the metal foil 30 is 5 μm or less, the response ability to form a microcircuit pattern (to control the line/space (L/S) to 10 to 15 μm) can be enhanced.

The surface roughness (Rz) of the metal foil 30 is 0.05 to 1.5 μm, preferably 0.05 to 1.0 μm, more preferably 0.05 to 0.4 μm. As described above, the surface roughness of the metal foil is transferred to the surface of the insulating base. As a result, the surface area of the insulating base is increased, ensuring sufficient adhesion. If sufficient adhesion is not ensured, the subsequent processes do not proceed or detachment or peeling may occur upon pattern formation. In addition, since the surface roughness of the metal foil used in the present invention is lower than those of metal foils used in previous inventions, a transmission loss due to the skin depth is small, which is more advantageous for 5G communication using high frequency.

The component of the metal foil 30 is not particularly limited. Specifically, the metal may be selected from the group consisting of copper, silver, gold, nickel, aluminum, and mixtures thereof.

For bonding of the metal foil 30 to the insulating base 20, the metal foil 30 is arranged on the insulating base 20 such that the plurality of projections 31 present on the metal foil 30 face the insulating base 20. That is, the surface of the metal foil 30 on which the plurality of projections 31 are present is bonded to the insulating base 20. This can ensure strong adhesion between the metal foil 30 and the insulating base 20.

The plurality of projections formed on the surface of the metal foil are bonded to the surface of the insulating base so that the surface roughness of the metal foil can be transferred to the insulating base. As described above, the metal foil may be laminated by pressurization under a constant pressure. In this process, the surface roughness of the metal foil can be transferred to the surface of the insulating base.

Specifically, as a result of this transfer, the insulating base may have the same surface roughness as the metal foil and may have 2 to 100 pores per unit area (μm²), specifically 5 to 20 pores/μm², more specifically 7 to 15 pores/μm². The pores can ensure a high adhesive strength of the insulating base.

As described above, the metal foil may be directly attached to form pores on the surface of the substrate. Alternatively, a primer is attached to the surface of the metal foil, the metal foil attached with the primer is attached to the surface of the substrate, and the metal foil is removed to roughen the substrate. That is, the primer attached to the metal foil can be used to roughen the surface of the substrate. The use of the primer can be selected when the metal foil cannot be used to roughen the surface of the substrate. Any material that can be attached to the surface of the substrate and can transfer the roughness of the metal foil may be used for the primer. The use of a polymer resin is more preferable for the subsequent process (see FIG. 8).

The present invention uses a process for circuit pattern formation, such as a semi-additive process (SAP) or a modified semi-additive process (mSAP), to form a circuit pattern on a substrate and is featured in that a metal foil having specific surface characteristics is bonded to a substrate before forming via holes, unlike the prior art in which via holes are formed in a substrate and electroless plating or sputtering is then performed to form seed layers for electroplating on the surface of the substrate and in the via holes. The feature of the present invention will be described in detail with reference to the drawings.

A method for forming a circuit pattern on a substrate according to one embodiment of the present invention includes preparing a substrate in which a metal base is bonded to an insulating base (step (a)), bonding a metal foil having one or more flat-topped projections onto the insulating base (step (b)), forming one or more via holes penetrating the insulating base and the metal foil (step (c)), forming a seed part on the inner walls of the via holes (step (d)), arranging a dry film on the metal foil and patterning the dry film (step (e)), and electroplating the via holes exposed by the patterning to form a circuit pattern (step (f)).

In step (a), a substrate is prepared in which a metal base 10 is bonded to an insulating base 20. In step (b), a metal foil 30 having one or more flat-topped projections is bonded onto the insulating base 20. Steps (a) and (b) are the same as those described above and a detailed description thereof will be omitted.

In step (c), one or more via holes H are formed in the substrate in which the metal base 10 is bonded to the insulating base 20. The via holes H penetrate the metal foil 30 and the insulating base 20 but not the metal base 10. The via holes H can be formed by a suitable technique commonly known in the art, for example, drilling or laser processing. The method of the present invention may further include, after forming the via holes (H), roughening the inner walls of the via holes (H) (desmear, for example, plasma desmear) and/or removing impurities (e.g., ash) present in the via holes H or on the surface of the metal foil 30.

In step (d), a seed part is formed on the inner walls of the via holes H. The seed part 40 enables plating or filling of the via holes H by subsequent electroplating. The seed part 40 may be formed using an electrically conductive material. The seed part 40 may be formed by coating the inner walls of the via holes H with a conductive resin composition or by electroless plating with an electroless plating solution. The conductive resin composition may include a conductive resin commonly known in the art and the electroless plating solution may be one that includes a copper ion source and is commonly known in the art.

In step (e), a dry film 50 is patterned depending on a desired circuit pattern. Specifically, a dry film 50 is patterned by arranging the dry film 50 on the metal foil 30 and exposing and developing the dry film 50 to form a desired circuit pattern. The exposure and development of the dry film 50 may be performed by suitable processes commonly known in the art.

In step (f), the via holes H and the surface of the metal foil 30 exposed by the patterning are electroplated to form a circuit pattern. The composition of an electroplating solution used for the electroplating is not particularly limited and may include a metal ion source, a strong acid, a halogen ion source, a brightener, a leveling agent, and a carrier.

The metal ion source may be a copper ion source, specifically copper sulfate pentahydrate.

The strong acid may be selected from the group consisting of sulfuric acid, hydrochloric acid, methanesulfonic acid, ethanesulfonic acid, propanesulfonic acid, trifluoromethanesulfonic acid, sulfonic acid, hydrobromic acid, fluoroboric acid, and mixtures thereof.

The halogen ion source may be a chlorine ion source, specifically hydrochloric acid.

The brightener may be selected from the group consisting of bis(3-sulfopropyl) disulfide (sodium salt), 3-mercapto-1-propanesulfonic acid (sodium salt), 3-amino-1-propanesulfonic acid, O-ethyl-S-(3-sulphopropyl)dithiocarbonate (sodium salt), 3-(2-benzthiazolyl-1-thio)-1-propanesulfonic acid (sodium salt), N,N-dimethyldithiocarbamic acid-(3-sulfopropyl) ester (sodium salt), and mixtures thereof.

The carrier may be a material commonly known in the art. Specifically, the carrier may be made of a metal or a polymer resin. The carrier made of a metal can effectively discharge static electricity generated during storage and transport of the metal foil. The carrier made of a polymer resin is easily separated from the metal foil. Thus, the material for the carrier can be suitably selected depending on each process and user's choice.

The electroplating of the via holes H and the exposed surface of the metal foil 30 with the electroplating solution ensures uniformity and reliability of a final circuit pattern while minimizing the formation of defects such as voids.

The method may further include, after step (f), peeling the patterned dry film 50 and etching remaining portions of the metal foil 30 exposed by the peeling of the dry film 50 with an etching composition to form a desired circuit pattern on the substrate (step (g)). The etching composition may be any of those commonly known in the art.

A further embodiment of the present invention provides a method for forming a circuit pattern on a substrate. Specifically, the method includes preparing a substrate in which a metal base is bonded to an insulating base (step (a′)), bonding a metal foil having one or more flat-topped projections onto the insulating base (step (b′)), peeling the metal foil having a surface roughness formed by the projections to transfer the surface roughness of the metal foil to the insulating base (step (c′)), forming one or more via holes penetrating the insulating base (step (d′)), forming a seed part on the surface of the insulating base having the via holes and on the inner walls of the via holes (step (e′)), arranging a dry film on the insulating base on which the seed part is formed and patterning the dry film (step (f′)), and electroplating the via holes exposed by the patterning to form a circuit pattern (step (g′)).

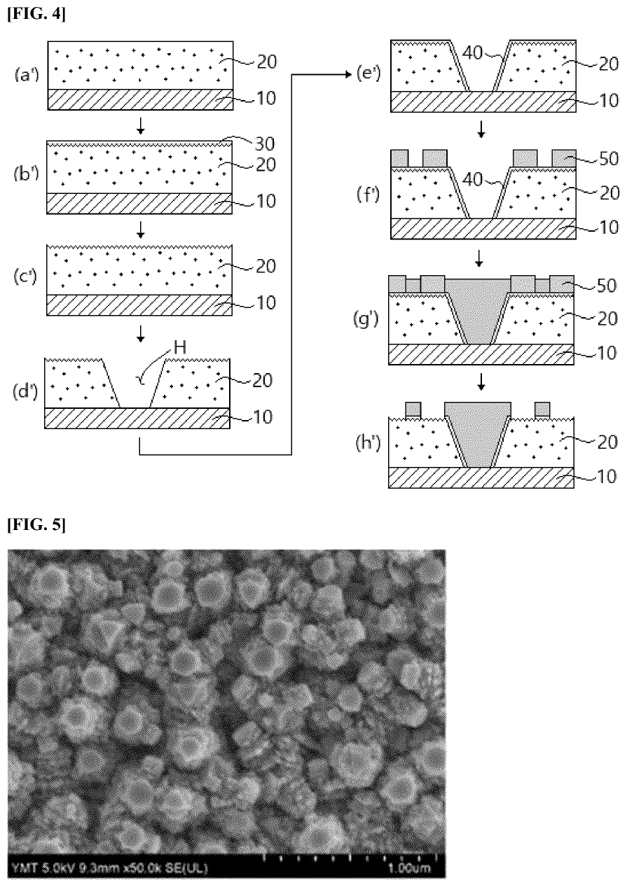

Referring specifically to FIG. 4, a substrate is prepared in which a metal base 10 is bonded to an insulating base 20 (step (a′)) and a metal foil 30 is bonded onto the insulating base 20 (step (b′)). Steps (a′) and (b′) are the same as those described above and a detailed description thereof will be omitted.

In step (c′), the surface roughness of the metal foil 30 is transferred to the insulating base 20. Specifically, the metal foil 30 having a surface roughness formed by one or more projections 31 and bonded to the insulating base 20 is peeled from the insulating base 20. As a result, the surface roughness of the metal foil 30 is transferred to the surface of the insulating base 20 to roughen the surface of the insulating base 20. The metal foil 30 may be peeled by copper etching, which is a general technique used to peel metal foils, specifically by using a copper etchant or by half etching. The transfer of the surface roughness of the metal foil 30 roughens the surface of the insulating base 20 and enables the formation of 2-100 pores/μm², which are the same as those described above.

The formation of the surface roughness of the insulating base 20 through the metal foil 30 can increase the adhesion between the seed part formed on the insulating base 20 and the insulating base for subsequent electroplating, which increases the possibility of microcircuit pattern formation.

In step (d′), one or more via holes H are formed in the substrate including the insulating base 20 with a surface roughness. The via holes H penetrate the insulating base 20 but not the metal base 10. The via holes H can be formed by a suitable technique commonly known in the art, for example, drilling or laser processing. The method of the present invention may further include, after forming the via holes (H), roughening the inner walls of the via holes (H) (desmear, for example, plasma desmear) and/or removing impurities (e.g., ash) present in the via holes H or on the surface of the insulating base 20.

In step (e′), a seed part 40 is formed on the surface of the insulating base 20 and on the inner walls of the via holes H. The seed part 40 enables plating or filling of the via holes H by subsequent electroplating to plate the surface of the insulating base 20. The seed part 40 may be formed using an electrically conductive material. The seed part 40 may be formed by electroless plating with an electroless plating solution. The electroless plating solution may be one that includes a copper ion source and is commonly known in the art.

In step (f′), a dry film 50 is patterned depending on a desired circuit pattern. Specifically, a dry film 50 is patterned by arranging the dry film 50 on the insulating base 20 on which the seed part 40 is formed and exposing and developing the dry film 50 to form a desired circuit pattern. The exposure and development of the dry film 50 may be performed by suitable processes commonly known in the art.

In step (g′), the via holes H and the surface of the seed part 40 exposed by the patterning are electroplated to form a circuit pattern. The composition of an electroplating solution used for the electroplating is not particularly limited and may include a metal ion source, a strong acid, a halogen ion source, a brightener, a leveling agent, and a carrier. The composition of the electroplating solution is the same as that described above and a detailed description thereof will be omitted.

The method may further include, after step (g′), peeling the patterned dry film 50 and etching remaining portions of the seed part 40 exposed by the peeling of the dry film 50 with an etching composition to form a desired circuit pattern on the substrate (step (h′)). The etching composition may be any of those commonly known in the art.

Since the present invention uses the metal foil having a specific surface structure, as described above, a circuit pattern can be formed on the substrate in an easy and economical manner while ensuring a high adhesive strength (bonding strength) to the insulating base, unlike the prior art using electroless plating or sputtering to form a circuit pattern on a substrate. The use of the metal foil enables the formation of a microcircuit pattern and can increase uniformity and reliability of the circuit pattern, contributing to the manufacture of boards (for example, circuit boards applied to 5G devices) where high-frequency signal transmission is required.

The present invention will be explained in more detail with reference to the following examples. However, these examples are provided for illustrative purposes and do not serve to limit the scope of the invention. It will be obvious to those skilled in the art that various modifications and changes are possible without departing from the scope and spirit of the invention.

### Preparative Example 1

A laminate of a Cu foil carrier and a release layer (consisting of an alloy layer of nickel and molybdenum and an organic layer of sodium mercaptobenzotriazole) was put into an electroless plating bath. As a result of electroless plating, a 1 μm thick metal foil (copper foil) was formed on the release layer. An electroless plating solution including 190-200 g/L of a metal ion source (CuSO₄·5H₂O), 0.01-0.1 g/L of a nitrogenous compound (guanine), 405-420 g/L of a chelating agent (potassium sodium tartrate), a pH adjusting agent (NaOH), and a reducing agent (28% formaldehyde) was used for the electroless plating. The electroless plating was performed at 30° C. for 10 min.

### Experimental Example 1

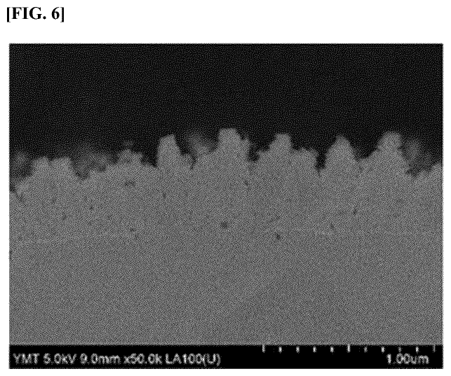

The surface and cross section of the metal foil formed in Preparative Example 1 were analyzed with a scanning electron microscope (SEM) and a cross section polisher (CP), respectively. The results are shown in FIGS. 5 and 6.

Referring to FIGS. 5 and 6, a plurality of projections with flat tops were formed on the surface of the metal foil prepared in Preparative Example 1.

### Example 1

A circuit pattern was formed using the method illustrated in claim 9 and FIG. 1.

### Experimental Example 2

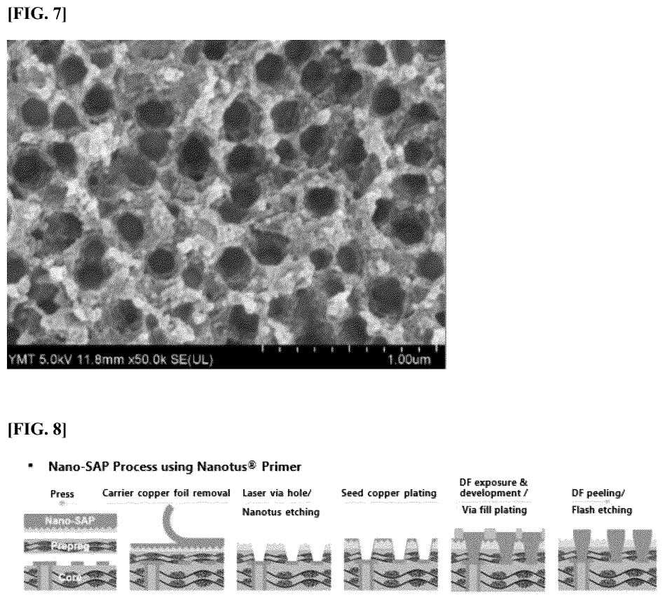

When the circuit pattern was formed in Example 1, the metal foil of Preparative Example 1 was bonded to an insulating base and peeled to transfer the surface roughness of the metal foil to the insulating base. Then, the surface of the insulating base was analyzed with a scanning electron microscope (SEM). The SEM image is shown in FIG. 7.

Referring to FIG. 7, the surface of the insulating base was roughened corresponding to the surface structure of the metal foil.

### Experimental Example 3

### Nanotus Cu Foil

A Nanotus Cu foil was laminated on a 100× 100 mm specimen (ABF GL-103, Ajinomoto).

The Cu foil was primarily laminated at a temperature of 100° C. and a pressure of 5 kg/m² for 60 sec, secondarily laminated at a temperature of 100° C. and a pressure of 5 kg/m² for 60 sec, and cured at a temperature of 130° C. for 30 min and at a temperature of 165° C. for 30 min.

After the lamination, the carrier copper foil was removed and copper electroplating (20 μm) was performed on the Nanotus Cu.

The adhesive strength was evaluated under the following conditions: peel test area 10 mm, test speed 50 mm/min, and angle 90°.

TABLE 1

| | Conventional SAP process | Example 1 |
|---|---|---|
| Maximum value | 365 g_{f}/cm | 702 g_{f}/cm |
| Minimum value | 442 g_{f}/cm | 796 g_{f}/cm |
| Average value | 410 g_{f}/cm | 740 g_{f}/cm |

1. A method for forming a circuit pattern on a substrate, comprising preparing a substrate in which a metal base is bonded to an insulating base, bonding a metal foil having one or more flat-topped projections onto the insulating base, and transferring the surface roughness of the metal foil to the insulating base.

2. The method according to claim 1, wherein the metal foil is bonded onto the insulating base such that the flat-topped projections face the surface of the insulating base.

3. The method according to claim 1, wherein each of the flat-topped projections comprises a protrusion having a truncated conical or truncated polygonal pyramidal shape and a plateau provided at the top end of the protrusion.

4. The method according to claim 3, wherein the protrusion has a plurality of microprojections formed on the surface thereof.

5. The method according to claim 1, wherein the surface roughness (Rz) of the metal foil is 0.05 to 1.5 μm.

6. The method according to claim 1, wherein the thickness of the metal foil is 5 μm or less.

7. The method according to claim 1, wherein the metal foil is formed by electroless plating.

8. The method according to claim 1, wherein 2 to 100 pores per unit area (μm²) are formed on the surface of the insulating base to which the roughness is transferred.

9. A method for forming a circuit pattern on a substrate, comprising preparing a substrate in which a metal base is bonded to an insulating base, bonding a metal foil having one or more flat-topped projections onto the insulating base, forming one or more via holes penetrating the insulating base and the metal foil, forming a seed part on the inner walls of the via holes, arranging a dry film on the metal foil and patterning the dry film, and electroplating the via holes exposed by the patterning to form a circuit pattern.

10. A method for forming a circuit pattern on a substrate, comprising preparing a substrate in which a metal base is bonded to an insulating base, bonding a metal foil having one or more flat-topped projections onto the insulating base, peeling the metal foil having a surface roughness formed by the projections to transfer the surface roughness of the metal foil to the insulating base, forming one or more via holes penetrating the insulating base, forming a seed part on the surface of the insulating base having the via holes and on the inner walls of the via holes, arranging a dry film on the insulating base on which the seed part is formed and patterning the dry film, and electroplating the via holes exposed by the patterning to form a circuit pattern.
